(19) United States
(12) Patent Application Publication
(10) Pub. No.: US 2026/0238251 A1
(43) Pub. Date: Aug. 13, 2026

(54) LOCAL OSCILLATOR SIGNAL GENERATION CIRCUIT AND GENERATION METHOD AND WIRELESS COMMUNICATION SYSTEM

(71) Applicant: Shanghai WUQI Microelectronics Co., Ltd., Shanghai (CN)

(72) Inventor: Xuehui CHEN, Shanghai (CN)

(73) Assignee: Shanghai WUQI Microelectronics Co., Ltd., Shanghai (CN)

(21) Appl. No.: 19/158,883

(22) PCT Filed: Mar. 15, 2024
(86) PCT No.: PCT/CN2024/081797

§ 371 Date: Aug. 22, 2025

(30) Foreign Application Priority Data
Mar. 30, 2023 (CN) 202310333246.X

(51) Int. Cl. H04B 1/403; H03L 7/093; H03L 7/099; H03L 7/18

(52) U.S. Cl. CPC H04B 1/403; H03L 7/093; H03L 7/099; H03L 7/18

(57) ABSTRACT

The present disclosure provides a local oscillator signal generation circuit and generation method and a wireless communication system. The local oscillator signal generation circuit includes an oscillator configured to generate a differential clock signal with a duty cycle of 50%; and a frequency divider connected to an output end of the oscillator and configured to perform half-integer frequency division on the differential clock signal and use a signal after the half-integer frequency division as a local oscillator signal. The present disclosure performs the half-integer frequency division on the clock signal output by the oscillator, and uses the signal as the local oscillator signal to participate in mixing, so that the frequency of the oscillator can avoid the frequency of the high-power device, thereby reducing frequency pulling of the clock signal output by the oscillator and reducing noise.

### FIELD OF TECHNOLOGY

The present disclosure relates to the field of wireless communication, and in particular to a local oscillation signal generation circuit and generation method and a wireless communication system.

### BACKGROUND

With the development of communication technologies, the demand for higher data transmission rates has grown significantly, leading to increasingly elevated clock frequencies within chips. This imposes stricter requirements on the phase noise performance of clock sources. Inductor-capacitor voltage-controlled oscillators (LC-VCOs), which amplify oscillation and output clock signals through an LC-based feedback loop, are increasingly adopted in high-performance clock synthesizers due to their superior phase noise characteristics. Meanwhile, semiconductor processes continue to evolve, enabling higher levels of chip integration. Various wireless RF communication systems now incorporate numerous high-power devices, such as power amplifiers (PAs) and mixers. To optimize the performance, these high-power devices often integrate on-chip inductors and capacitors. During operation, they emit electromagnetic energy into the surrounding space. When such devices are integrated with the LC-VCO while operating at proximate frequencies, the LC-VCO becomes highly susceptible to electromagnetic radiation interference due to its inherent LC-based structure containing both inductors and capacitors. This results in significant detrimental effects, such as frequency pulling (a phenomenon where a frequency signal injects into and perturbs an oscillator frequency with a frequency close to it, causing its oscillation frequency to be drawn toward the interference frequency in a repetitive pattern, which degrades frequency stability), phase noise degradation, and generation of spurious frequencies.

The conventional engineering solution involves configuring the LC-VCO's oscillation frequency to operate away from the frequency bands of the high-power devices. However, existing approaches either fail to effectively mitigate frequency pulling effects induced by the RF high-power devices on the oscillator, or prove unsuitable for low-power systems. Consequently, achieving effective frequency pulling suppression while maintaining compatibility with the low-power systems has emerged as one of the most pressing technical challenges to be addressed by those skilled in the art.

It should be noted that the above introduction to the technical background is only for the convenience of providing a clear and complete description of the technical solutions of the present disclosure and for the convenience of understanding by those skilled in the art. It cannot be considered that the above technical solutions are well known to those skilled in the art simply because they are described in the technical background of the present disclosure.

### SUMMARY

The present disclosure provides a local oscillator signal generation circuit and generation method and a wireless communication system, so as to solve the problem of frequency pulling of the oscillator in the related art.

To achieve the above objective and other related objectives, the present disclosure provides a local oscillator signal generation circuit, at least comprising:

An oscillator configured to generate a differential clock signal with a duty cycle of 50%; and

a frequency divider connected to an output end of the oscillator and configured to perform half-integer frequency division on the differential clock signal and use a signal after the half-integer frequency division as a local oscillator signal.

Optionally, the local oscillator signal generation circuit further comprises a duty cycle calibration module, wherein the duty cycle calibration module is connected to an output end of the frequency divider and configured to adjust a duty cycle of the local oscillator signal.

Optionally, the oscillator is an LC-VCO.

Further optionally, the frequency divider comprises a first frequency division unit, a second frequency division unit and a frequency multiplier unit;

the first frequency division unit and the second frequency division unit respectively comprise a first tri-state gate and a second tri-state gate which are cascaded in sequence, a control end of each tri-state gate receives the differential clock signal, and the clock signals of two tri-state gates are opposite; the clock signal of the first tri-state gate of the first frequency division unit and the clock signal of the first tri-state gate of the second frequency division unit are opposite;

a first input end of the frequency multiplier unit is connected to an output end of the first frequency division unit, a second input end of the frequency multiplier unit is connected to an output end of the second frequency division unit, and an output end of the frequency multiplier unit outputs the signal after the half-integer frequency division and is connected to an input end of the first frequency division unit and an input end of the second frequency division unit.

Further optionally, the first frequency division unit and the second frequency division unit respectively comprise M transmission modules connected to an output end of the second tri-state gate, M being a natural number greater than or equal to 1, and the transmission modules being cascaded in sequence; each transmission module comprises a third tri-state gate and an inverter connected to an output end of the third tri-state gate, and a control end of the third tri-state gate receives the differential clock signal;

the clock signal of each tri-state gate of the first frequency division unit is opposite in sequence, and the clock signal of each tri-state gate of the second frequency division unit is opposite in sequence.

Further optionally, the frequency multiplier unit is a NAND logic unit.

Further optionally, the frequency divider further comprises a buffer unit, and the buffer unit is connected to the output end of the frequency multiplier unit and configured to improve a driving capability of the local oscillator signal.

To achieve the above objective and other related objectives, the present disclosure further provides a local oscillator signal generation method, at least comprising:

Obtaining a differential clock signal with a duty cycle of 50%, performing half-integer frequency division on the differential clock signal, and using a signal after the half-integer frequency division as a local oscillator signal.

Optionally, the local oscillator signal generation method further comprises adjusting a duty cycle of the signal after the half-integer frequency division to make the duty cycle of the local oscillator signal be 50%.

To achieve the above object and other related objectives, the present disclosure further provides a wireless communication system, at least comprising:

An antenna, a receiving path, a transmitting path, and the local oscillator signal generation circuit described above;

the local oscillator signal generation circuit is configured to provide a local oscillator signal;

the receiving path is connected to the antenna and an output end of the local oscillator signal generation circuit and configured to down-convert a radio frequency (RF) signal received by the antenna based on the local oscillator signal;

the transmitting path is connected to the output end of the local oscillator signal generation circuit and the antenna, and configured to up-convert a baseband signal based on the local oscillator signal to obtain the RF signal and transmit the RF signal through the antenna.

As described above, the local oscillator signal generation circuit and generation method and the wireless communication system of the present disclosure have the following beneficial effects:
1. The local oscillator signal generation circuit and generation method and the wireless communication system of the present disclosure perform the half-integer frequency division on the clock signal output by the oscillator and use the signal as the local oscillator signal to participate in mixing, so that the frequency of the oscillator can avoid the frequency of the high-power devices, thereby reducing frequency pulling of the clock signal output by the oscillator and reducing noise.
2. The frequency divider of the present disclosure has a simple structure, a small area, low power consumption and strong scalability.
3. The frequency divider of the present disclosure is implemented based on the CMOS technology, and has low cost, good integration and low power consumption.
4. The local oscillator signal generation circuit of the present disclosure is applicable to any RF front-end circuit that requires the local oscillator signal, such as Bluetooth and Wi-Fi, and has a wide range of applications.

### BRIEF DESCRIPTION OF THE DRAWINGS

FIG. 1 is a schematic structural diagram of a transmitter.

FIG. 2 is a schematic diagram of a principle of frequency pulling occurring in a transmitter.

FIG. 3 is a schematic structural diagram of a transmitter that avoids frequency pulling using a frequency division technology.

FIG. 4 is a schematic diagram of a principle that frequency pulling still exists after integer frequency division is adopted.

FIG. 5 is a schematic structural diagram of a fractional frequency divider using capacitors and inductors.

FIG. 6 is a schematic structural diagram of a local oscillator signal generation circuit according to the present disclosure.

FIG. 7 is a schematic structural diagram of a frequency divider of the present disclosure that implements 1.5 frequency division.

FIG. 8 is a schematic structural diagram of a frequency divider of the present disclosure that implements 2.5 frequency division.

FIG. 9 is another schematic structural diagram of a local oscillator signal generation circuit according to the present disclosure.

FIG. 10 is a schematic diagram of waveforms of nodes of the frequency divider in FIG. 7.

FIG. 11 is a schematic diagram of waveforms of nodes of the frequency divider in FIG. 8.

FIG. 12 is a schematic structural diagram of a wireless communication system according to the present disclosure.

### Reference Numerals

1 Transmitter
11 Frequency synthesizer
111 Oscillator
112 Frequency divider
113 Phase detector filter unit
12 Mixer
13 Pre-amplifier
14 RF power amplifier
15 Antenna
16 Frequency divider
161 Frequency division unit
162 Frequency division unit
163 Mixer
164 Frequency selective network
2 Local oscillator signal generation circuit
21 Oscillator
22 Frequency divider
22a First frequency division unit
22b Second frequency division unit
221 First tri-state gate
222 Second tri-state gate
223 Transmission module
2231 Third tri-state gate
2232 Inverter
22c Frequency multiplier unit
22d Buffer unit
23 Duty cycle calibration module
3 Antenna
4 Receiving path
5 Transmitting path

### DETAILED DESCRIPTION

The following describes the embodiments of the present disclosure through specific examples, and those skilled in the art can easily understand other advantages and effects of the present disclosure from the contents disclosed in this specification. The present disclosure can also be implemented or applied through other different specific embodiments, and the details in this specification can also be modified or changed in various ways based on different viewpoints and applications without departing from the spirit of the present disclosure.

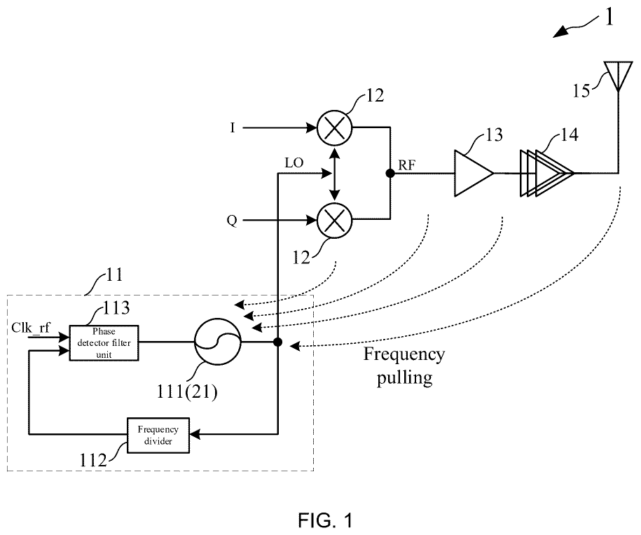

Please refer to FIGS. 1-12. It should be noted that the diagrams provided in this embodiment are only used to illustrate the basic concept of the present disclosure in a schematic manner, and the diagrams only show components related to the present disclosure rather than being drawn according to the number, shape and size of components in actual implementation. In actual implementation, the type, quantity and proportion of each component may be changed arbitrarily, and the component layout may also be more complicated.

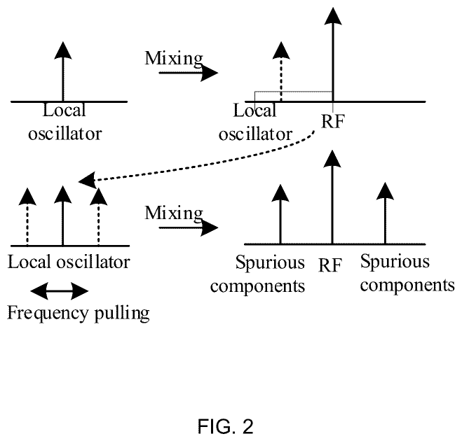

As shown in FIG. 1, a transmitter 1 of a wireless communication system adopts a direct up-conversion architecture (baseband signals are directly up-converted into RF signals). A clock signal generated by a frequency synthesizer 11 (e.g., a phase-locked loop structure is adopted, including an oscillator 111, a frequency divider 112 and a phase detector filter unit 113) is directly used as a local oscillator signal LO of the transmitter; baseband signals I and Q are up-converted by a mixer 12 to obtain the RF signals RF; the RF signals RF are sent to a pre-amplifier 13 and an RF power amplifier 14 for amplification; and finally transmitted through an antenna 15. Since the direct up-conversion architecture is adopted, operation frequencies of the mixer 12, the pre-amplifier 13, the RF power amplifier 14 and the antenna 15 approximate a local oscillator frequency, their power signals run into the oscillator 111 of the frequency synthesizer 11 through various coupling paths, thereby pulling an oscillation frequency of the oscillator 111, i.e., pulling the frequency of the local oscillator signal LO. As shown in FIG. 2, the local oscillator signal is mixed with the baseband signal to obtain the RF signal. Since the local oscillator signal is a high-frequency signal, its frequency is relatively close to that of the RF signal; accordingly, the RF signal pulls the local oscillator signal, causing the frequency of the local oscillator signal to change back and forth on both sides of the original frequency. After the local oscillator signal pulled by the frequency is mixed with the baseband signal, the final result at an output end is that the noise of the RF signal becomes larger, unnecessary spurious components are generated, and the signal-to-noise ratio becomes worse.

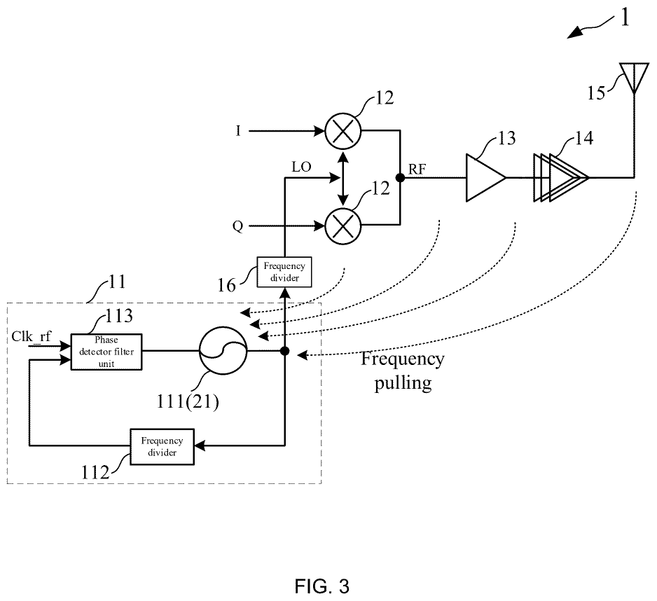

As shown in FIG. 3, frequency pulling can be avoided using the frequency multiplier technology. That is, the clock signal output by the oscillator 111 is subjected to frequency division by a frequency divider 16 and used as the local oscillator signal LO. In this way, the operation frequency of the power device is far away from the frequency of the oscillator 111, avoiding direct frequency pulling.

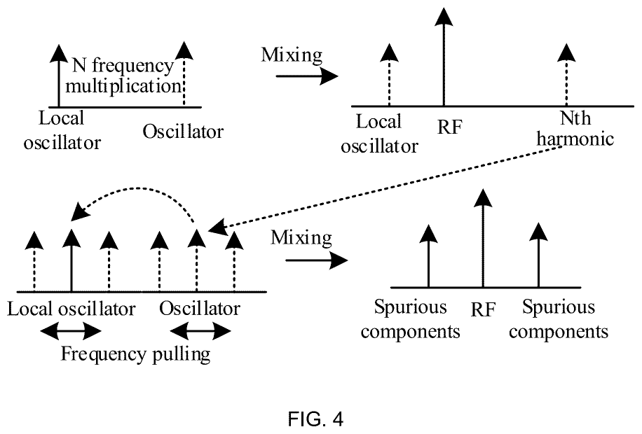

If the frequency divider 16 performs an integer multiple frequency division, and a frequency division ratio is N, an Nth harmonic of the RF signal approximates the oscillator frequency, and there is still the problem of the frequency of the harmonic pulling an oscillator base frequency. As shown in FIG. 4, the oscillator output signal is subjected to N frequency division to obtain the local oscillator signal, and the local oscillator signal is mixed with the baseband signal to obtain the RF signal. In this case, the frequency of the oscillator output signal is away from the RF signal, i.e., the RF signal does not cause frequency pulling to the oscillator output signal; however, the Nth harmonic of the RF signal approximates the frequency of the oscillator output signal, i.e., the Nth harmonic of the RF signal pulls the oscillator output signal, and the local oscillator signal obtained after the oscillator output signal is subjected to N frequency division is also affected by the frequency pulling, and the final output RF signal has the problem of poor signal-to-noise ratio.

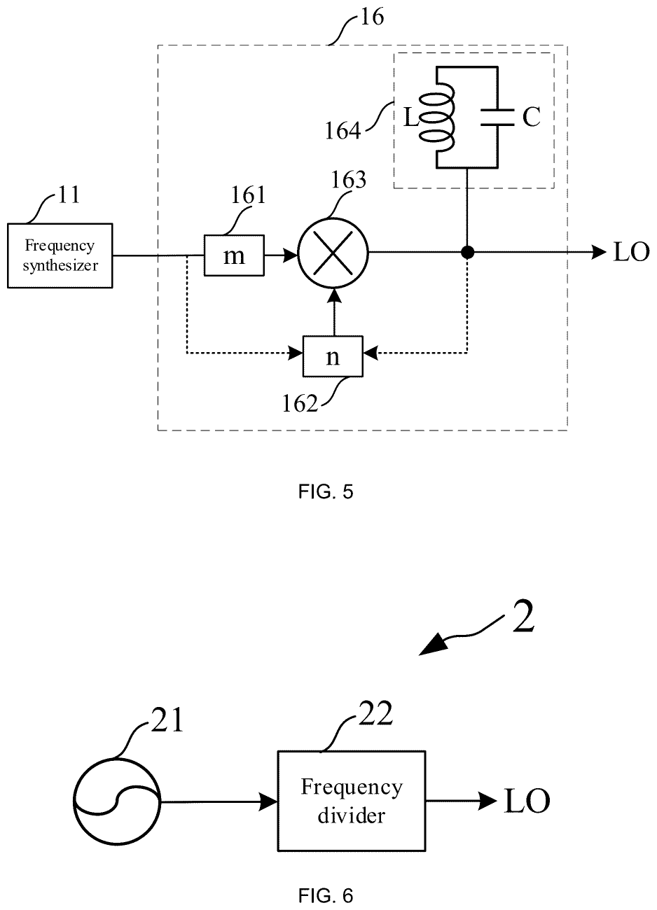

If the frequency divider 16 is a fractional frequency divider, the frequency pulling of the harmonic can be effectively avoided. As long as a fractional frequency division ratio is selected appropriately, there are almost no fractional high-order harmonic in the RF signal. The approach of generating the fractional frequency division in the RF system is to use a mixer to mix two or more clock signals with a certain relationship, and then select required frequency components through a frequency selective network. As shown in FIG. 5, a frequency division unit 161 generates a clock signal of m frequency division, and a frequency division unit 162 generates a clock signal of n frequency division. According to different combinations of frequency division coefficients, a mixer 163 can generate various fractional frequency components, and the frequency selective network 164 selects the required frequency components as the local oscillator signal LO. The mixer 163 has a complex structure and huge power consumption, and is not applicable in low-power systems. In order to achieve specific selection characteristics, the frequency selective network 164 often requires integrated inductors L and capacitors C, which occupy a large chip area and are not applicable in low-cost projects. In addition, when the local oscillator frequency changes or the process changes, the process migration capability and scalability of the circuit using the mixer 163 and the frequency selective network 164 are also challenged.

Accordingly, the present disclosure provides a local oscillator signal generation circuit and generation method and a wireless communication system based on a CMOS technology, which can effectively reduce the frequency pulling of the oscillator by the high-power RF devices, and the half-integer frequency divider of the present disclosure has the advantages of simple structure, small area, low power consumption and strong scalability.

As shown in FIG. 6, the present disclosure provides a local oscillator signal generation circuit 2. The local oscillator signal generation circuit 2 comprises:

An oscillator 21 and a frequency divider 22.

As shown in FIG. 6, the oscillator 21 is configured to generate differential clock signals clkp and clkn with a duty cycle of 50%.

Specifically, the oscillator 21 is configured to generate a clock signal; in this embodiment, the oscillator 21 is an LC-VCO. For example, the oscillator 21 is disposed in the frequency synthesizer 11, as shown in FIG. 1 and FIG. 3, an output of the oscillator 21 is collected to enter into the frequency divider 112 for frequency division, and a signal after frequency division and a reference signal Clk_rf are simultaneously input into the phase detector filter unit 113, a frequency difference of the two signals (the feedback signal and the reference signal) is obtained by phase detection, and then a DC pulse voltage is output after filtering to control the frequency of the oscillator 21. After multiple feedback adjustments, the output of the oscillator 21 is stable at an expected value. The phase-locked loop circuit is simple, has the characteristics of broadband tracking and narrowband filtering, and has many general integrated circuits, which has low cost and small size, and can be preferably used as the frequency synthesizer 11. In practical application, any circuit structure that can generate the clock signal based on the oscillator is suitable for the frequency synthesizer 11, which is not limited to this embodiment.

As shown in FIG. 6, the frequency divider 22 is connected to an output end of the oscillator 21 and configured to perform half-integer frequency division on the differential clock signal and use a signal after the half-integer frequency division as the local oscillator signal LO.

Specifically, the frequency divider 22 is used for half-integer frequency division, and the frequency division ratio includes but is not limited to 1.5, 2.5, 3.5, and 4.5, which is not limited herein. In this case, the frequency of the clock signal output by the oscillator 21 is a half-integer multiple of the frequency of the local oscillator signal LO, and the harmonic of the RF signal obtained by mixing the local oscillator signal is away from the frequency of the oscillator output signal, thereby avoiding the frequency pulling.

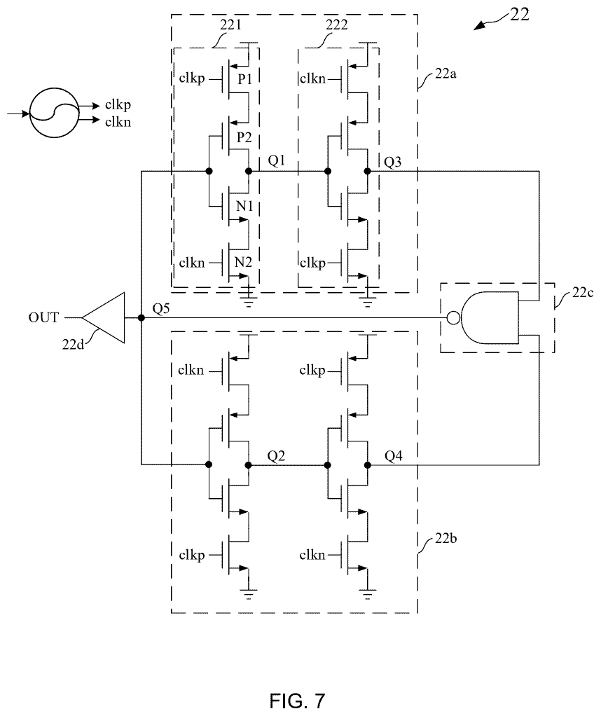

Specifically, as shown in FIG. 7, merely by way of example, the frequency divider 22 comprises a first frequency division unit 22a, a second frequency division unit 22b and a frequency multiplier unit 22c. The first frequency division unit 22a and the second frequency division unit 22b respectively comprise a first tri-state gate 221 and a second tri-state gate 222 which are cascaded in sequence, a control end of each tri-state gate receives the differential clock signal, and the clock signals of the two tri-state gates (the first tri-state gate 221 and a second tri-state gate 222) are opposite; the clock signal of the first tri-state gate of the first frequency division unit 22a and the clock signal of the first tri-state gate of the second frequency division unit 22b are opposite. A first input end of the frequency multiplier unit 22c is connected to an output end of the first frequency division unit 22a, a second input end of the frequency multiplier unit 22c is connected to an output end of the second frequency division unit 22b, and an output end of the frequency multiplier unit 22c outputs the signal after the half-integer frequency division and is connected to an input end of the first frequency division unit 22a and an input end of the second frequency division unit 22b. The frequency divider 22 of the embodiment can be used for implement 1.5 frequency division.

More specifically, as shown in FIG. 7, the input end of the first tri-state gate 221 of the first frequency division unit 22a serves as the input end of the first frequency division unit 22a, the output end of the first tri-state gate 221 is connected to the input end of the second tri-state gate 222, and the output end of the second tri-state gate 222 serves as the output end of the first frequency division unit 22a. Each tri-state gate comprises two PMOS transistors and two NMOS transistors, and the output has a high-level state, a low-level state, and a high-impedance state; where a source of a first PMOS transistor P1 is connected to a power supply voltage, a gate serves as a first control end of the tri-state gate, and a drain is connected to a source of a second PMOS transistor P2; a gate of the second PMOS transistor P2 is connected with a gate of a first NMOS transistor N1 as an input end of the tri-state gate; a drain of the second PMOS transistor P2 is connected with a drain of the first NMOS transistor N1 as an output end of the tri-state gate; a source of the first NMOS transistor N1 is connected to a drain of a second NMOS transistor N2; a gate of the second NMOS transistor N2 serves as a second control end of the tri-state gate, and a source is grounded; the first control end and the second control end of the tri-state gate receive inverted clock signals. In this embodiment, the first control end of the first tri-state gate 221 of the first frequency division unit 22a receives the clock signal clkp, and the second control end receives the clock signal clkn; the clock signal of the second tri-state gate 222 is inverted with that of the first tri-state gate 221, i.e., the first control end of the second tri-state gate 222 receives the clock signal clkn, and the second control end receives the clock signal clkp. The connection relationship between the first tri-state gate and the second tri-state gate of the second frequency division unit 22b is the same as that of the first frequency division unit 22a, which is not repeated herein; the difference is that the first control end of the first tri-state gate of the second frequency division unit 22b receives the clock signal clkn, and the second control end receives the clock signal clkp; the first control end of the second tri-state gate receives the clock signal clkp, and the second control end receives the clock signal clkn.

More specifically, as shown in FIG. 7, the frequency multiplier unit 22c is implemented by a NAND logic unit. The NAND logic unit includes but is not limited to a NAND gate. Any circuit structure that can implement the NAND logic is applicable, which is not limited to this embodiment.

More specifically, as shown in FIG. 7, as another embodiment of the present disclosure, the frequency divider 22 further comprises a buffer unit 22d, and the buffer unit 22d is connected to the output end of the frequency multiplier unit 22c to improve the drive capability of the local oscillation signal LO.

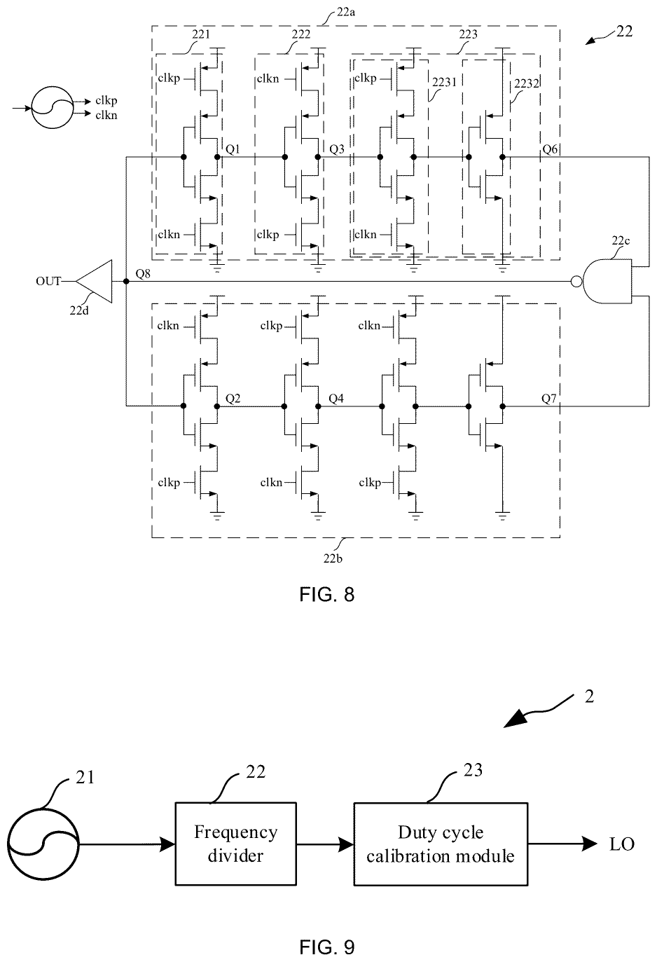

Specifically, for example, the first frequency division unit 22a and the second frequency division unit 22b respectively comprise M transmission modules 223, M being a natural number greater than or equal to 1; each transmission module 223 comprises a third tri-state gate 2231 and an inverter 2232 connected to an output end of the third tri-state gate 2231. As shown in FIG. 8, in this embodiment, M is set to 1; then one transmission module 223 is added to the first frequency division unit 22a and the second frequency division unit 22b, respectively. In the first frequency division unit 22a, an input end of the transmission module 223 is connected to the output end of the second tri-state gate 222, and an output end of the transmission module 223 serves as the output end of the first frequency division unit 22a; the first control end of the third tri-state gate 2231 receives the clock signal clkp, and the second control end receives the clock signal clkn. The connection relationship of the transmission module of the second frequency division unit 22b is the same as that of the first frequency division unit 22a, which is not repeated herein; the difference is that the first control end of the third tri-state gate of the second frequency division unit 22b receives the clock signal clkn, and the second control end receives the clock signal clkp.

It should be noted that in the solution of FIG. 8, M is set to 1, which is used for achieving 2.5 frequency division. When the frequency division ratio needs to be increased, the value of M can be adjusted. For example, when M=2, the frequency division ratio is 3.5, when M=3, the frequency division ratio is 4.5, and so on. By increasing the count of the transmission modules, a frequency divider with a higher half-integer frequency division ratio is expanded, which is not repeated herein. When M is greater than or equal to 2, the transmission modules are cascaded in sequence, and the clock signal of each tri-state gate of the first frequency division unit 22a is opposite in sequence, and the clock signal of each tri-state gate of the second frequency division unit 22b is opposite in sequence. In this case, the clock signals of the corresponding tri-state gates of the first frequency division unit 22a and the second frequency division unit 22b are opposite, which is not repeated herein. Generally, the half-integer division ratio is 1.5, 2.5, 3.5 and 4.5. Continuing to increase the half-integer division ratio further reduces the energy of the frequency pulling (the higher the harmonic order, the weaker the energy). However, when the frequency of the local oscillator signal is determined, the larger the half-integer division ratio, the higher the oscillator frequency, and the correspondingly larger the oscillator area and the more complex the circuit. Accordingly, the energy of the frequency pulling and the oscillator area can be comprehensively considered to determine the appropriate half-integer division ratio, which is not limited to this embodiment.

As shown in FIG. 9, as another embodiment of the present disclosure, the local oscillator signal generation circuit 2 further comprises a duty cycle calibration module 23. The duty cycle calibration module 23 is connected to the output end of the frequency divider 22 and configured to adjust a duty cycle of the local oscillator signal LO. The adjusted signal is provided to the mixer as the local oscillator signal LO.

Specifically, the duty cycle calibration module 23 is configured to adjust the duty cycle of the local oscillator signal LO to meet the subsequent requirements of the system for the clock duty cycle. In this embodiment, the duty cycle of the local oscillator signal LO is adjusted to 50%. For example, the duty cycle calibration module 23 comprises a duty cycle detection unit and a duty cycle correction unit. The duty cycle detection unit uses an integrator and a comparator to detect the duty cycle of the output signal of the frequency divider 22 (an ideal clock signal duty cycle is 50%, and its DC component is considered as an average value of the high and low levels; when the duty cycle is less than 50%, the DC component is less than the average value; or the DC component is greater than the average value; accordingly, the function of detecting the duty cycle can be realized by the integrator and the comparator). The duty cycle correction unit fixes a rising edge (or a falling edge), and adjusts the delay of the falling edge (or the rising edge) based on an output signal of the duty cycle detection unit, so as to achieve the purpose of adjusting the duty cycle. In practical application, any circuit structure that can realize duty cycle adjustment is applicable to the present disclosure, which is not limited to this embodiment.

The present disclosure further provides a local oscillator signal generation method, comprising: obtaining a differential clock signal with a duty cycle of 50%, performing half-integer frequency division on the differential clock signal, and using a signal after the half-integer frequency division as a local oscillator signal. As another example, the local oscillator signal generation method further comprises adjusting a duty cycle of the signal after the half-integer frequency division to make the duty cycle of the local oscillator signal be 50%. The adjusted duty cycle may also be set according to actual system requirements, which is not limited to this embodiment.

The local oscillator signal generation method can be implemented based on software, hardware or a combination of software and hardware. In this embodiment, the local oscillator signal generation method is implemented based on the above local oscillator signal generation circuit 2. Specifically, as shown in FIGS. 6-9, the oscillator 21 generates differential clock signals clkp and clkn with a duty cycle of 50%, and the frequency divider 22 performs the half-integer frequency division on the differential clock signals clkp and clkn, and the clock signals after the half-integer frequency division are used as the local oscillator signal LO, or the clock signals after the half-integer frequency division are subjected to duty cycle adjustment and output as the local oscillator signal LO.

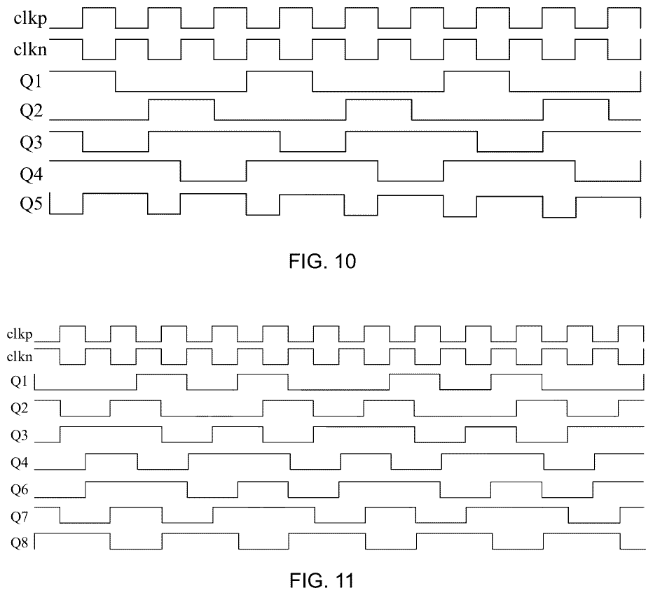

As shown in FIG. 7 and FIG. 10, when 1.5 frequency division is implemented based on the frequency divider in FIG. 7, circuit nodes Q1 and Q2, Q3 and Q4 are orthogonal clock signals that perform 3 frequency division on the input clock signals clkp and clkn, respectively. Sending a pair of orthogonal clock signals to the NAND gate can double the clock frequency. After the orthogonal signals of 3 frequency division are multiplied, a divide-by-1.5 clock is output at the circuit node Q5. The signals of the circuit node Q5 can be used as the local oscillator clock through an appropriate buffer unit. The present disclosure makes full use of the complementary characteristics of the CMOS process and the parasitic capacitance of the circuit nodes. Q1, Q2, Q3, and Q4 can still maintain the charge after the respective tri-state gates are closed, thereby keeping the state unchanged, which greatly simplifies the circuit design, improves the operation speed of the frequency divider, reduces the circuit area, and reduces the current consumption.

As shown in FIG. 8 and FIGS. 11, 2.5 frequency division is implemented based on the frequency divider in FIG. 8, the circuit nodes Q1 and Q2, Q3 and Q4, Q6 and Q7 are orthogonal clock signals that perform 5 frequency division on the input clock signals clkp and clkn, respectively. After multiplying of the orthogonal clocks, a fixed divide-by-2.5 clock is obtained at the circuit node Q8.

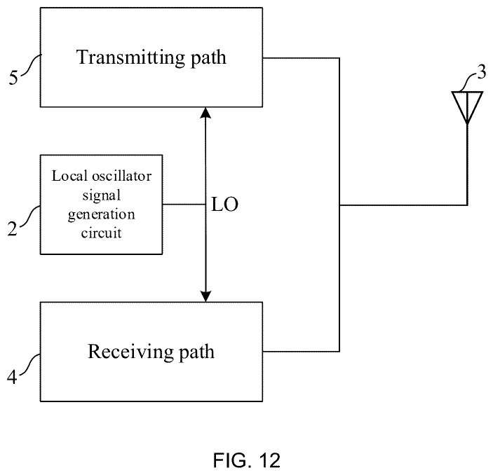

As shown in FIG. 12, the present disclosure further provides a wireless communication system, the wireless communication system comprises:

The local oscillator signal generation circuit 2, the antenna 3, a receiving path 4 and a transmitting path 5.

As shown in FIG. 12, the local oscillator signal generation circuit 2 is configured to provide the local oscillator signal LO. The structure and the working principle of the local oscillator signal generation circuit 2 are as mentioned above, which are not repeated herein.

As shown in FIG. 12, the receiving path 4 is connected to the antenna 3 and the output end of the local oscillator signal generation circuit 2 and configured to down-convert an RF signal received by the antenna 3 based on the local oscillator signal LO.

Specifically, for example, the receiving path 4 comprises a low noise amplifier, a filter connected to an output end of the low noise amplifier, and a mixer connected to an output end of the filter; the mixer receives the local oscillator signal to implement a down-conversion function. Any circuit structure that can down-convert the RF signal based on the local oscillator signal is applicable to the receiving path 4 of the present disclosure, which is not limited to this embodiment.

As shown in FIG. 12, the transmitting path 5 is connected to the output end of the local oscillator signal generation circuit 2 and the antenna 3 and configured to up-convert a baseband signal based on the local oscillator signal LO to obtain the RF signal and transmit the RF signal through the antenna 3.

Specifically, for example, the transmitting path 5 comprises a mixer, a pre-amplifier connected to an output end of the mixer, and a power amplifier connected to an output end of the pre-amplifier; the mixer receives the local oscillator signal to implement an up-conversion function. Any circuit structure that can up-convert the baseband signal based on the local oscillator signal is applicable to the transmitting path 5 of the present disclosure, which is not limited to this embodiment.

As shown in FIG. 12, in this embodiment, the receiving path 4 and the transmitting path 5 share the same antenna 3 through time division multiplexing, and the antenna 3 switches (the switch is not shown in the figure) different paths as needed to achieve the receive or transmit function.

The wireless communication system of the present disclosure can effectively reduce the frequency pulling of the RF high-power devices on the oscillator, and has a simple structure, low cost, low power consumption and strong scalability.

In summary, the present disclosure provides the local oscillator signal generation circuit and generation method and the wireless communication system. The local oscillator signal generation circuit comprises the oscillator configured to generate the differential clock signal with the duty cycle of 50%; the frequency divider connected to the output end of the oscillator and configured to perform half-integer frequency division on the differential clock signal and use the signal after the half-integer frequency division as the local oscillator signal. The local oscillator signal generation circuit and generation method and the wireless communication system of the present disclosure perform the half-integer frequency division on the clock signal output by the oscillator, and use the signal as the local oscillator signal to participate in mixing, so that the frequency of the oscillator can avoid the frequency of the high-power device, thereby reducing the frequency pulling of the clock signal output by the oscillator and reducing noise; the frequency divider of the present disclosure has a simple structure, small area, low power consumption and strong scalability; the frequency divider of the present disclosure is implemented based on the CMOS process, and has low cost, good integration, and low power consumption; the local oscillator signal generation circuit is suitable for any RF front-end circuit that requires the local oscillator signal, such as Bluetooth and Wi-Fi, and has a wide range of applications. Therefore, the present disclosure effectively overcomes the shortcomings in the related art and has high industrial value of application.

The above embodiments are merely illustrative of the principles and effects of the present disclosure, and are not intended to limit the present disclosure. Anyone familiar with the art may modify or alter the above embodiments without departing from the spirit and scope of the present disclosure. Therefore, all equivalent modifications or alterations made by those having ordinary skills in the art without departing from the spirit and technical concept disclosed by the present disclosure shall still be covered by the claims of the present disclosure.

What is claimed is:

1. A local oscillator signal generation circuit, wherein the local oscillator signal generation circuit at least comprises:
an oscillator configured to generate a differential clock signal with a duty cycle of 50%; and
a frequency divider connected to an output end of the oscillator and configured to perform half-integer frequency division on the differential clock signal and use a signal after the half-integer frequency division as a local oscillator signal.

2. The local oscillator signal generation circuit according to claim 1, further comprising a duty cycle calibration module, wherein the duty cycle calibration module is connected to an output end of the frequency divider and configured to adjust a duty cycle of the local oscillator signal.

3. The local oscillator signal generation circuit according to claim 1, wherein the oscillator is an LC-VCO.

4. The local oscillator signal generation circuit according to claim 1, wherein the frequency divider comprises a first frequency division unit, a second frequency division unit and a frequency multiplier unit;
the first frequency division unit and the second frequency division unit respectively comprise a first tri-state gate and a second tri-state gate which are cascaded in sequence, a control end of each tri-state gate receives the differential clock signal, and the clock signals of two tri-state gates are opposite; the clock signal of the first tri-state gate of the first frequency division unit and the clock signal of the first tri-state gate of the second frequency division unit are opposite;
a first input end of the frequency multiplier unit is connected to an output end of the first frequency division unit, a second input end of the frequency multiplier unit is connected to an output end of the second frequency division unit, and an output end of the frequency multiplier unit outputs the signal after the half-integer frequency division and is connected to an input end of the first frequency division unit and an input end of the second frequency division unit.

5. The local oscillator signal generation circuit according to claim 4, wherein the first frequency division unit and the second frequency division unit respectively comprise M transmission modules connected to an output end of the second tri-state gate, M being a natural number greater than or equal to 1, and the transmission modules being cascaded in sequence; each transmission module comprises a third tri-state gate and an inverter connected to an output end of the third tri-state gate, and a control end of the third tri-state gate receives the differential clock signal;
the clock signal of each tri-state gate of the first frequency division unit is opposite in sequence, and the clock signal of each tri-state gate of the second frequency division unit is opposite in sequence.

6. The local oscillator signal generation circuit according to claim 4, wherein the frequency multiplier unit is a NAND logic unit.

7. The local oscillator signal generation circuit according to claim 4, wherein the frequency divider further comprises a buffer unit, and the buffer unit is connected to the output end of the frequency multiplier unit and configured to improve a driving capability of the local oscillator signal.

8. A local oscillator signal generation method, wherein the local oscillator signal generation method at least comprises:
obtaining a differential clock signal with a duty cycle of 50%, performing half-integer frequency division on the differential clock signal, and using a signal after the half-integer frequency division as a local oscillator signal.

9. The local oscillator signal generation method according to claim 8, further comprising adjusting a duty cycle of the signal after the half-integer frequency division to make the duty cycle of the local oscillator signal being 50%.

10. A wireless communication system, wherein the wireless communication system at least comprises:
an antenna, a receiving path, a transmitting path, and the local oscillator signal generation circuit as claimed in claim 1; wherein
the local oscillator signal generation circuit is configured to provide a local oscillator signal;
the receiving path is connected to the antenna and an output end of the local oscillator signal generation circuit, and configured to down-convert a radio frequency (RF) signal received by the antenna based on the local oscillator signal;
the transmitting path is connected to the output end of the local oscillator signal generation circuit and the antenna, and configured to up-convert a baseband signal based on the local oscillator signal to obtain an RF signal and transmit the RF signal through the antenna.
